(19) United States
(12) Patent Application Publication
(10) Pub. No.: US 2023/0026201 A1
(43) Pub. Date: Jan. 26, 2023

(54) MOTOR DRIVE CONTROL DEVICE AND MOTOR DRIVE CONTROL METHOD

(71) Applicant: MINEBEA MITSUMI Inc., Nagano (JP)

(72) Inventors: Shinji TOTSUKA, Fukuroi-shi, Shizuoka (JP); Hiroki KOKUBO, Fukuroi-shi, Shizuoka (JP); Shigemi MASUDA, Fukuroi-shi, Shizuoka (JP)

(21) Appl. No.: 17/758,408

(22) PCT Filed: Oct. 30, 2020
(86) PCT No.: PCT/JP2020/040749

§ 371 Date: Jul. 6, 2022

(30) Foreign Application Priority Data
Jan. 14, 2020 (JP) 2020-003424

(51) Int. Cl. H02P 27/08; H02P 6/28; H02M 1/00; H03M 1/12

(52) U.S. Cl. CPC H02P 27/08; H02P 6/28; H02M 1/0009; H03M 1/12

(57) ABSTRACT

A motor drive control device capable of reliably acquiring currents of coils of two phases by a one-shunt current detection system is provided. The motor drive control device includes: a motor drive unit including an inverter circuit; a single current detection circuit connected to a direct current line of the inverter circuit, and detecting a current flowing through the direct current line; and a control circuit unit performing analog-to-digital conversion processing of the current to take in the current, and performing PWM control on the motor drive unit. The control circuit unit acquires, from the current detection circuit, a detection result of a first current and a second current being currents of coils of two phases among coils of three phases in a half cycle of one PWM cycle, and, when the A/D conversion processing of at least one of the first current and the second current is unsuccessful, reacquires, in the same PWM cycle or a next or subsequent PWM cycle, a detection result of only the current unsuccessful in the A/D conversion processing, and performs the A/D conversion processing of the reacquired detection current.

### TECHNICAL FIELD

The present invention relates to a motor drive control device and a motor drive control method capable of reliably acquiring currents of coils of two phases by a one-shunt current detection system.

### BACKGROUND ART

In a conventional motor drive control device, a one-shunt current detection system is known. In the one-shunt current detection system, currents of coils of two phases among coils of three phases are detected by a shunt resistor connected to a direct current line of an inverter circuit.

For example, Patent Document 1 describes a device estimating (reproducing) an output current of an inverter circuit from a current detected in the past when a current of one of coils of two phases cannot be detected in the one-shunt current detection system.

Particularly, when current detection timings of coils of two phases are close, a problem that a current of a coil of a second phase cannot be detected may occur.

### CITATION LIST

### Patent Literature

Patent Document 1: JP 2004-64903 A

### SUMMARY OF INVENTION

### Technical Problem

As in Patent Document 1, when an output current of an inverter circuit is estimated from a current detected in the past, a certain degree of estimation accuracy is expected in a steady state. However, an influence of a voltage applied to a motor is not reflected in estimation in a transient state, and thus excellent estimation accuracy cannot be expected. Further, since estimation is performed, a current value used for vector control includes an error, and the error is not preferable for smooth drive of the motor.

Thus, an object of the present invention is to provide a motor drive control device and a motor drive control method capable of reliably taking in currents of coils of two phases by a one-shunt current detection system with a simple circuit configuration.

### Solution to Problem

A motor drive control device according to the present invention includes:

a motor drive unit including an inverter circuit including a plurality of switching elements, the inverter circuit supplying alternating current power to coils of three phases of a motor;

a single current detection circuit connected to a direct current line of the inverter circuit, the single current detection circuit detecting a current flowing through the direct current line; and

a control circuit unit performing analog-to-digital conversion processing of the current detected in the current detection circuit to take in the current, and performing PWM control on the motor drive unit, wherein

the control circuit unit

acquires, from the current detection circuit, a detection result of a first current and a second current being currents of coils of two phases among coils of three phases in a half cycle of one PWM cycle, and

when the analog-to-digital conversion processing of at least one of the first current and the second current is unsuccessful, reacquires, in the same PWM cycle or a next or subsequent PWM cycle, a detection result of only the current unsuccessful in the analog-to-digital conversion processing, and performs the analog-to-digital conversion processing of the reacquired detection current.

In the motor drive control device according to the present invention,

the control circuit unit preferably

acquires, from the current detection circuit, a detection result of the first current and the second current in a first half of one PWM cycle, and

when the analog-to-digital conversion processing of at least one of the first current and the second current is unsuccessful, reacquires, in a first half of a next PWM cycle, a detection result of only the current unsuccessful in the analog-to-digital conversion processing, and performs the analog-to-digital conversion processing of the reacquired detection current.

In the motor drive control device according to the present invention,

the control circuit unit preferably

acquires, from the current detection circuit, a detection result of the first current and the second current in a second half of one PWM cycle, and

when the analog-to-digital conversion processing of at least one of the first current and the second current is unsuccessful, reacquires, in a second half of a next PWM cycle, a detection result of only the current unsuccessful in the analog-to-digital conversion processing, and performs the analog-to-digital conversion processing of the reacquired detection current.

In the motor drive control device according to the present invention,

the control circuit unit preferably

acquires, from the current detection circuit, a detection result of the first current and the second current in a second half of one PWM cycle, and

when the analog-to-digital conversion processing of at least one of the first current and the second current is unsuccessful, reacquires, in a first half of a next PWM cycle, a detection result of only the current unsuccessful in the analog-to-digital conversion processing, and performs the analog-to-digital conversion processing of the reacquired detection current.

In the motor drive control device according to the present invention,

the control circuit unit preferably

acquires, from the current detection circuit, a detection result of the first current and the second current in a first half of one PWM cycle, and

when the analog-to-digital conversion processing of at least one of the first current and the second current is unsuccessful, reacquires, in a second half of the same PWM cycle, a detection result of only the current unsuccessful in the analog-to-digital conversion processing, and performs the analog-to-digital conversion processing of the reacquired detection current.

In the motor drive control device according to the present invention,

when the analog-to-digital conversion processing of the current having been unable to be subjected to the analog-to-digital conversion processing is unsuccessful again, the control circuit unit preferably repeats, in a next or subsequent PWM cycle, reacquisition of a detection result of only the current unsuccessful again in the analog-to-digital conversion processing, and the analog-to-digital conversion processing.

In the motor drive control device according to the present invention, when the analog-to-digital conversion processing is unsuccessful for a predetermined number of times or more, the control circuit unit preferably acquires again a detection result of both of the first current and the second current in a half cycle of one PWM cycle.

The present invention is a motor drive control method for performing PWM control on a motor drive unit including an inverter circuit including a plurality of switching elements, the inverter circuit supplying alternating current power to coils of three phases of a motor, the motor drive control method including:

acquiring a detection result of a first current and a second current being currents of coils of two phases among coils of three phases in a half cycle of one PWM cycle;

performing analog-to-digital conversion processing of the first current and the second current; and

when the analog-to-digital conversion processing of at least one of the first current and the second current is unsuccessful, reacquiring, in the same PWM cycle or a next or subsequent PWM cycle, a detection result of only the current unsuccessful in the analog-to-digital conversion processing, and performing the analog-to-digital conversion processing of the reacquired detection current.

### Advantageous Effects of Invention

The present invention can provide a motor drive control device and a motor drive control method capable of reliably acquiring currents of coils of two phases by a one-shunt current detection system with a simple circuit configuration.

### BRIEF DESCRIPTION OF DRAWINGS

FIG. 1 is a diagram illustrating a circuit configuration of a motor drive control device according to an embodiment of the present invention.

FIG. 2 is a diagram for explaining a known current acquisition method.

FIG. 3 is an example of a timing chart of current acquisition and AD conversion processing in the motor drive control device according to an embodiment of the present invention.

FIG. 4 is an example of a flowchart of the current acquisition and the AD conversion processing in the motor drive control device according to an embodiment of the present invention.

### DESCRIPTION OF EMBODIMENTS

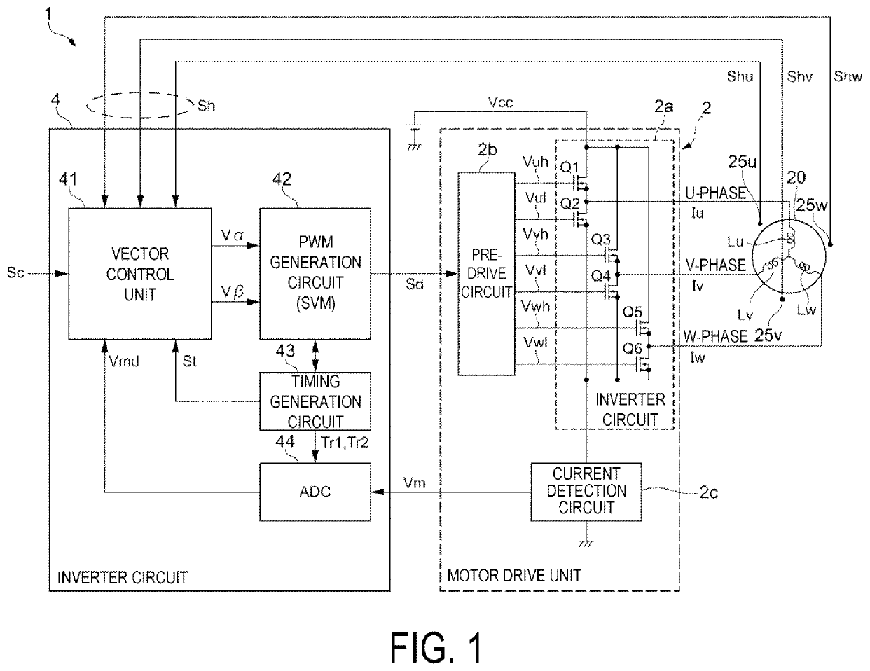

FIG. 1 is a diagram illustrating a circuit configuration of a motor drive control device according to an embodiment of the present invention.

A motor drive control device 1 includes a motor drive unit 2 and a control circuit unit 4.

The motor drive unit 2 includes an inverter circuit 2a, a pre-drive circuit 2b, and a single current detection circuit 2c.

The inverter circuit 2a includes six switching elements Q1 to Q6, and supplies alternating current power to coils Lu, Lv, and Lw of three phases (U-phase, V-phase, and W-phase) of a motor 20. The switching elements Q1, Q3, and Q5 are high-side switching elements formed of an N-channel MOSFET disposed at a positive electrode side of a power supply Vcc, and a power supply voltage of the power supply Vcc is applied. The switching elements Q2, Q4, and Q6 are low-side switching elements formed of the N-channel MOSFET disposed at a negative electrode side of the power supply Vcc. A connection point of the switching elements Q1 and Q2 is connected to the coil Lu of the U-phase, a connection point of the switching elements Q3 and Q4 is connected to the coil Lv of the V-phase, and a connection point of the switching elements Q5 and Q6 is connected to the coil Lw of the W-phase.

The pre-drive circuit 2b includes six output terminals connected to gate terminals of the six switching elements Q1 to Q6 of the inverter circuit 2a. The pre-drive circuit 2b outputs output signals Vuh, Vul, Vvh, Vvl, Vwh, and Vwl, based on a drive control signal Sd output from the control circuit unit 4, and controls an on/off operation of the switching elements Q1 to Q6.

The current detection circuit 2c is connected to a direct current line of the inverter circuit 2a, and detects a current flowing through the direct current line. The current detection circuit 2c includes, for example, a shunt resistor, and detects currents Iu, Iv, and Iw of the coils Lu, Lv, and Lw of the three phases from a voltage across both ends of the shunt resistor. The current detection circuit 2c outputs, as a detection result, a detection voltage signal Vm corresponding to the detected current to the control circuit unit 4.

In the motor 20, three Hall elements (one example of position detection sensors) 25u, 25v, and 25w outputting signals according to a rotation position of the motor 20 are disposed corresponding to the coils Lu, Lv, and Lw of the three phases. The respective Hall elements 25u, 25v, and 25w detect magnetic poles of a rotor, and output Hall signals Shu, Shy, and Shw (collectively referred to as Sh). The Hall signal Sh is input to the control circuit unit 4.

Note that the position detection sensor is not limited to the Hall element, and the motor drive control device 1 may be a sensor-less system without including the position detection sensor.

The control circuit unit 4 is, for example, a microcomputer, includes a vector control unit 41, a PWM generation circuit 42, a timing generation circuit 43, and an analog-to-digital converter (ADC) 44, and performs PWM control on the motor drive unit 2. For example, a speed command signal Sc being a signal related to a rotation speed of the motor 20 is input from the outside to the control circuit unit 4.

The vector control unit 41 outputs voltage values Vα and Vβ to the PWM generation circuit 42 (spatial vector modulation circuit: SVM) according to known vector control.

The PWM generation circuit 42 outputs the drive control signal Sd to the motor drive unit 2, and performs PWM control on the motor drive unit 2.

The timing generation circuit 43 starts a counter of timing generation in synchronization with a count start of PWM, and triggers the analog-to-digital converter 44. Specifically, the timing generation circuit 43 outputs a trigger signal Tr1 to the analog-to-digital converter 44 at current intake timings t1, t2, t11, t12, . . . described below. Further, the timing generation circuit 43 outputs a trigger signal Tr2 to the analog-to-digital converter 44 at current calculation timings t3, t13, . . . described below.

The analog-to-digital converter 44 performs analog-to-digital conversion (hereinafter also described as AD conversion) processing of the detection voltage signal Vm corresponding to the currents Iu, Iv, and Iw, based on the trigger signal Tr1, and also outputs a digital voltage signal Vmd to the vector control unit 41, based on the trigger signal Tr2.

Subsequently, when the timing generation circuit 43 outputs a timing signal St to the vector control unit 41, the vector control unit 41 performs vector control from current values of three phases and rotation angle sensor information, and calculates a magnitude of energization of the PWM generation circuit 42.

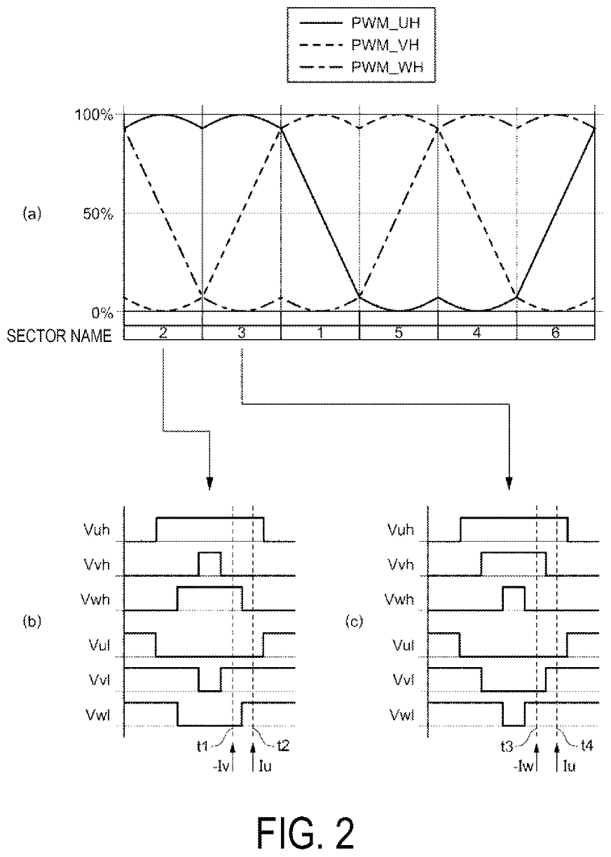

FIG. 2 is a diagram for explaining a known current acquisition method.

FIG. 2(a) is a waveform generated by spatial vector modulation, FIG. 2(b) is a PWM waveform in a sector 2, and FIG. 2(c) is a PWM waveform in a sector 3.

As illustrated in FIG. 2(a), in the sector 2, PWM_UH has PWM on-duty of approximately 100%, and PWM_VH has PWM on-duty of approximately 0%. Thus, correspondingly, as illustrated in FIG. 2(b), the output signal Vuh for turning on the switching element Q1 has a long on-period, and the output signal Vvh for turning on the switching element Q3 has a short on-period. Further, as illustrated in FIG. 2(a), in the sector 2, PWM on-duty of PWM_WH is intermediate between PWM on-duty of PWM_UH and PWM on-duty of WM_VH. Thus, correspondingly, as illustrated in FIG. 2(b), the output signal Vwh for turning on the switching element Q5 has a length of an on-period being intermediate between the periods of Vuh and Vvh. Note that, in FIG. 2(b), the output signals Vul, Vvl, and Vwl for turning on the switching elements Q2, Q4, and Q6 are complementary to the output signals Vuh, Vvh, and Vwh, respectively.

In FIG. 2(b), at time t1, since the output signals Vuh, Vwh, and Vvl are at a high level, the switching elements Q1, Q4, and Q5 are turned on. Thus, a current (−Iv) flowing from the coil Lv of the V-phase can be acquired. Further, at time t2, since the output signals Vuh, Vvl, and Vwl are at the high level, the switching elements Q1, Q4, and Q6 are turned on. Thus, a current (Iu) flowing into the coil Lu of the U-phase can be acquired. As a result, from a law that a sum of currents of three phases is zero, a current (Iw) (=−Iu−Iv) can be determined from the current (−Iv) and the current (Iu) by calculation.

As in a case of FIG. 2(c), the current (−Iw) flowing from the coil Lw of the W-phase can be acquired at time t3, the current (Iu) flowing into the coil Lu of the U-phase can be acquired at time t4, and the current (Iv) (=−Iu−Iw) can be determined by calculation.

In this way, in the known current acquisition method, currents of coils of two phases determined for each sector are acquired in a first or second half cycle of one PWM cycle, and a current of a coil of one remaining phase is determined by calculation.

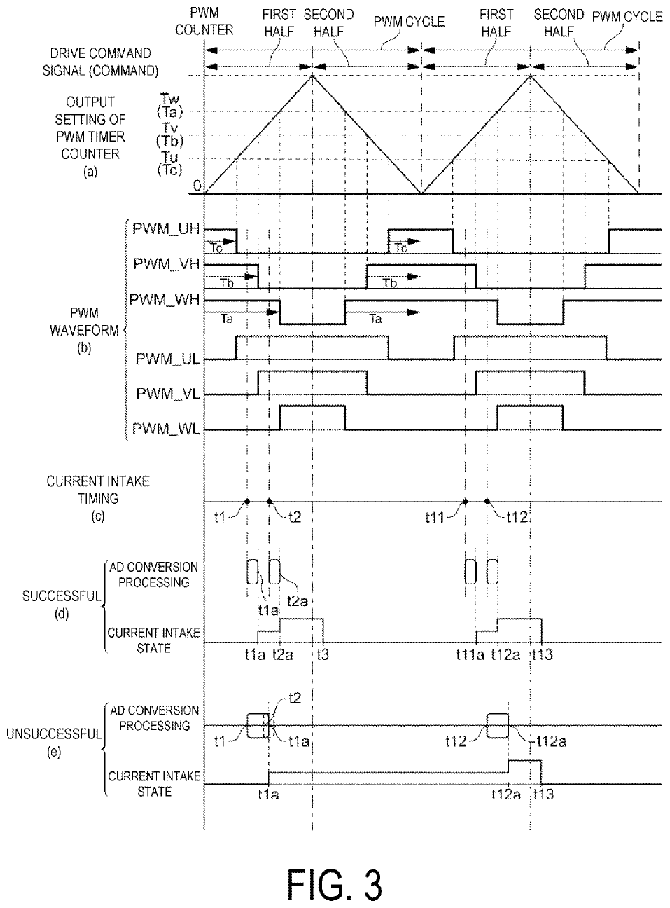

FIG. 3 is an example of a timing chart of current acquisition and AD conversion processing in the motor drive control device according to an embodiment of the present invention.

FIG. 3 is a timing chart when the control circuit unit 4 acquires a detection result of currents (a first current (−Iu) and a second current (Iw) in the present example) of coils of two phases detected in the current detection circuit 2c in a half cycle (a first half cycle in the present example) of one PWM cycle, performs analog-to-digital conversion processing of the acquired detection result of the currents of the two phases, and takes in a current.

FIG. 3 illustrates, from the top, (a) output setting of a PWM timer counter, (b) a PWM waveform, (c) a current intake timing, (d) a successful state of the AD conversion processing of coil currents of two phases and a current intake state at that time, and (e) an unsuccessful state of the AD conversion processing of a coil current of one phase and a current intake state at that time. Note that the current intake state refers to an intake state of a current as a result of performing the AD conversion processing of a detection current acquired from the current detection circuit 2c in the control circuit unit 4.

As illustrated in FIG. 3(a), the PWM timer counter has a triangular waveform. One PWM cycle is divided into a first half and a second half.

As illustrated in FIG. 3(b), PWM waveforms PWM_UH, PWM_VH, and PWM_WH correspond to the output signals Vuh, Vvh, and Vwh for turning on the switching elements Q1, Q3, and Q5, and PWM waveforms PWM_UL, PWM_VL, and PWM_WL correspond to the output signals Vul, Vvl, and Vwl for turning on the switching elements Q2, Q4, and Q6. Further, the PWM waveforms PWM_UH, PWM_VH, and PWM_WH and the PWM waveforms PWM_UL, PWM_VL, and PWM_WL are complementary to each other.

At time t1, since the PWM waveforms PWM_VH, PWM_WH, and PWM_UL are at the high level, the switching elements Q2, Q3, and Q5 are turned on. Thus, a detection result of a current (−Iu: first current) flowing from the coil Lu of the U-phase is acquired. The AD conversion processing is triggered at time t1, and, as illustrated in FIG. 3(d), the AD conversion processing of the first current (−Iu) starts at time t1, and the AD conversion processing of the first current (−Iu) is successful and ends at time t1 a. Since the AD conversion processing is successful, a flag of a current intake state is set at time t1 a. For example, in a case of a 8-bit flag, 00000001 is set.

Similarly, at time t2, since the PWM waveforms PWM_WH, PWM_UL, and PWM_VL are at the high level, the switching elements Q2, Q4, and Q5 are turned on. Thus, a detection result of a current (Iw: second current) flowing into the coil Lw of the W-phase is acquired. Further, the AD conversion processing of the second current (Iw) starts at time t2, and the AD conversion processing is successful and ends at time t2a. Since the AD conversion processing of the second current (Iw) is successful, a flag of a current intake state is set at time t2a. For example, in a case of a 8-bit flag, 00000011 is set.

At time t3, a third current (Iv=−Iu−Iw) is calculated from the first current (−Iu) and the second current (Iw). Further, the flag of the current intake state is cleared.

Similarly, in a next PWM cycle, a detection result of the first current (−Iu) is acquired at time t11, and, when the AD conversion processing is successful, a flag of a current intake state is set at time t11a, and a detection result of the second current (Iw) is acquired at time t12, and, when the AD conversion processing is successful, a flag of a current intake state is set at time t12a, and the third current (Iv) is calculated at time t13.

This current intake operation is performed in each PWM cycle.

Next, a description will be given to an operation when a detection result of currents (a first current (−Iu) and a second current (Iw) in the present example) of coils of two phases in a half cycle (a first half cycle in the present example) of one PWM cycle is acquired, and the AD conversion processing of a current (the second current (Iw) in the present example) of one phase among the currents of the coils of the two phases is unsuccessful (current intake is unsuccessful).

As illustrated in FIG. 3(e), at time t1, a detection result of the first current (−Iu) is acquired, and the AD conversion processing of the first current (−Iu) starts. When the AD conversion processing is successful and ends at time t1 a, a flag of a current intake state is set. Here, time t1 a of ending the AD conversion processing of the first current (−Iu) is later than time t2 of starting the AD conversion processing of the second current (Iw) based on the acquired detection result of the second current (Iw). Thus, the AD conversion processing of the second current (Iw) cannot start, and the AD conversion processing of the second current (Iw) is unsuccessful. Thus, for the second current (Iw), a detection result of the second current (Iw) is reacquired in a next PWM cycle, and the AD conversion processing of the reacquired detection result of the second current (Iw) is performed again. Note that, since the AD conversion processing of the first current (−Iu) is successful, a digital value of the first current (−Iu) is stored, and a detection result of the first current (−Iu) is not acquired in the next PWM cycle.

At time t12, a detection result of the second current (Iw) is acquired, and the AD conversion processing of the second current (Iw) starts. When the AD conversion processing ends at time t12a, a flag of a current intake state is set.

At time t13, the third current (Iv=−Iu−Iw) is calculated from the first current (−Iu) taken in the previous PWM cycle and the second current (Iw) taken in the current PWM cycle.

In this way, according to the present invention, when the AD conversion processing of a current of one phase among currents of coils of two phases has been unable to end in a half cycle of one PWM cycle, a detection result of only the current of one phase having been unable to be subjected to the AD conversion processing completely is reacquired and the AD conversion processing is performed again, and thus the currents of the coils of the two phases can be reliably taken in by one-shunt current detection system with a simple circuit configuration.

Particularly, even when current detection timings of coils of two phases are close and the AD conversion processing of a current of one of the phases is unsuccessful, a measured current value is used instead of using an estimated current value, and thus high accuracy can be achieved.

Further, according to the present invention, currents of two phases can be reliably taken in without a special restriction on processing time (processing speed) of AD conversion, and thus an expensive microcomputer does not need to be used, and a cost can be reduced.

In the embodiment described above, a detection result of the first current (−Iu) and the second current (Iw) is acquired in a first half of one PWM cycle, and the AD conversion processing of the second current (Iw) is unsuccessful, and thus a detection result of the second current (Iw) is acquired in a first half of a next PWM cycle, and the AD conversion processing is performed. However, the present invention is not limited to the embodiment (case 1) described above, and cases 2 to 4 are also conceivable as illustrated in Table 1.

TABLE 1

| | ONE PWM CYCLE | | NEXT PWM CYCLE | |
|---|---|---|---|---|
| | FIRST | SECOND | FIRST | SECOND |
| | HALF | HALF | HALF | HALF |
| CASE 1 | ✓ | | ✓ | |
| CASE 2 | | ✓ | | ✓ |
| CASE 3 | | ✓ | ✓ | |
| CASE 4 | ✓ | ✓ | | |

In the case 2, a detection result of the first current (−Iu) and the second current (Iw) is acquired in a second half of one PWM cycle, and the AD conversion processing of the second current (Iw) is unsuccessful, and thus a detection result of the second current (Iw) is acquired in a second half of a next PWM cycle, and the AD conversion processing is performed.

In the case 3, a detection result of the first current (−Iu) and the second current (Iw) is acquired in a second half of one PWM cycle, and the AD conversion processing of the second current (Iw) is unsuccessful, and thus a detection result of the second current (Iw) is acquired in a first half of a next PWM cycle, and the AD conversion processing is performed.

In the case 4, a detection result of the first current (−Iu) and the second current (Iw) is acquired in a first half of one PWM cycle, and the AD conversion processing of the second current (Iw) is unsuccessful, and thus a detection result of the second current (Iw) is acquired in a second half of the same PWM cycle, and the AD conversion processing is performed.

Further, in the embodiment described above, the AD conversion processing of the second current (Iw) is successful in a next PWM cycle. However, when the AD conversion processing of the second current (Iw) cannot also be performed again in the next PWM cycle, reacquisition of a detection result of the second current (Iw) unable to be subjected to the AD conversion processing again, and the AD conversion processing may be repeated in the next or subsequent PWM cycle.

However, when the AD conversion processing of the second current (Iw) is unsuccessful for a predetermined number of times or more in one sector, it is preferable to return to a first stage so as to acquire again a detection result of both of the first current (−Iu) and the second current (Iw) in a half cycle of one PWM cycle.

Further, in the embodiment described above, a case where the AD conversion processing of the second current (Iw) among the first current (−Iu) and the second current (Iw) is unsuccessful has been described, but the same applies to a case where the AD conversion processing of the first current (−Iu) is unsuccessful.

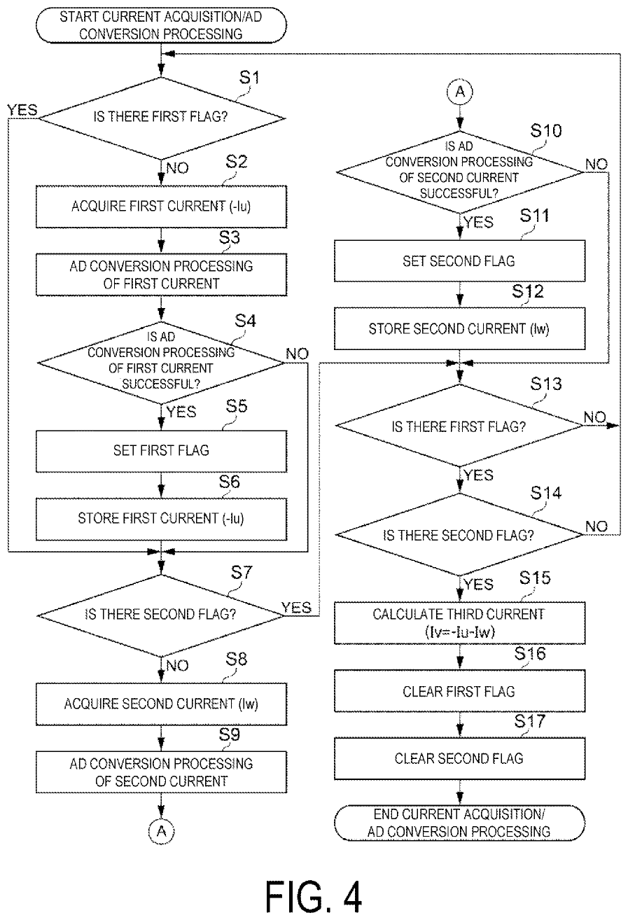

FIG. 4 is an example of a flowchart of the current acquisition and the AD conversion processing in the motor drive control device according to an embodiment of the present invention.

As a first example, a case where the AD conversion processing of both of a first current and a second current is successful will be described.

In step S1, for example, whether a flag of a first current intake state is set in a memory (not illustrated) in the control circuit unit 4 is checked. An initial value of the flag is 0, and the flag of the first current intake state is not set (No in step S1), and thus the processing proceeds to step S2.

In step S2, a detection result of a first current (−Iu) is acquired.

In step S3, the AD conversion processing of the first current is performed.

Steps S2 and S3 correspond to the operation at time t1 in FIGS. 3(c) and 3(d). In other words, when the timing generation circuit 43 outputs the trigger signal Tr1 to the analog-to-digital converter 44 at time t1, the analog-to-digital converter 44 acquires a detection result of the first current detected by the current detection circuit 2c, and performs the AD conversion processing of the first current.

In step S4, whether the AD conversion processing of the first current is successful is determined. When the AD conversion processing of the first current is successful (Yes), the processing proceeds to step S5.

In step S5, the flag of the first current intake state is set in the memory.

In step S6, the first current (−Iu) is stored in the memory.

Steps S4 to S6 correspond to the operation at time t1 a in FIG. 3(d).

In step S7, whether a flag of a second current intake state is set in the memory is checked. An initial value of the flag is 0, and the flag of the second current intake state is not set (No in step S7), and thus the processing proceeds to step S8.

In step S8, a detection result of a second current (Iw) is acquired.

In step S9, the AD conversion processing of the second current is performed.

Steps S8 and S9 correspond to the operation at time t2 in FIGS. 3(c) and 3(d). In other words, when the timing generation circuit 43 outputs the trigger signal Tr1 to the analog-to-digital converter 44 at time t2, the analog-to-digital converter 44 acquires a detection result of the second current detected by the current detection circuit 2c, and performs the AD conversion processing of the second current.

In step S10, whether the AD conversion processing of the second current is successful is determined. When the AD conversion processing of the second current is successful (Yes), the processing proceeds to step S11.

In step S11, the flag of the second current intake state is set in the memory.

In step S12, the second current (Iw) is stored in the memory.

Steps S10 to S12 correspond to the operation at time t2a in FIG. 3(d).

In step S13, whether the flag of the first current intake state is set in the memory is checked. The flag of the first current intake state is set in step S5 described above (Yes), and thus the processing proceeds to step S14.

In step S14, whether the flag of the second current intake state is set in the memory is checked. The flag of the second current intake state is set in the memory in step S11 described above (Yes), and thus the processing proceeds to step S15.

In step S15, a third current (Iv=−Iu−Iw) is calculated from the first current (−Iu) and the second current (Iw).

In step S16, the flag of the first current intake state is cleared.

In step S17, the flag of the second current intake state is cleared.

Steps S15 to 17 correspond to the operation at time t3 in FIG. 3(d). In other words, when the timing generation circuit 43 outputs the trigger signal Tr2 to the analog-to-digital converter 44 at time t3, the analog-to-digital converter 44 calculates the third current, and outputs, to the vector control unit 41, the digital voltage signal Vmd acquired by performing analog-to-digital conversion on the first to third currents.

As a second example, a case where the AD conversion processing of a first current is successful, and the AD conversion processing of a second current is unsuccessful at the first time and is successful at the second time will be described.

Steps S1 to S9 are the same as steps S1 to S9 in the first example.

In step S10, when the AD conversion processing of the second current is unsuccessful (No), the processing proceeds to step S13.

In step S13, the processing proceeds to step S14 because the flag of the first current intake state is set (Yes).

In step S14, the processing returns to step S1 because the flag of the second current intake state is not set (No).

In step S1, the processing proceeds to step S7 because the flag of the first current intake state is set (Yes).

In step S7, the processing proceeds to step S8 because the flag of the second current intake state is not set (No).

In step S8, a detection result of the second current (Iw) is acquired.

In step S9, the AD conversion processing of the second current is performed.

Steps S8 and S9 correspond to the operation at time t12 in FIGS. 3(c) and 3(e).

In step S10, whether the AD conversion processing of the second current is successful is determined, and, when the AD conversion processing is successful (Yes), the processing proceeds to step S11.

In step S11, the flag of the second current intake state is set in the memory.

In step S12, the second current (Iw) is stored in the memory.

Steps S10 to S12 correspond to the operation at time t12ain FIG. 3(e).

In step S13, the processing proceeds to step S14 because the flag of the first current intake state is set (Yes).

In step S14, the processing proceeds to step S15 because the flag of the second current intake state is set (Yes).

In step S15, a third current (Iv=−Iu−Iw) is calculated from the first current (−Iu) taken in the previous PWM cycle and the second current (Iw) taken in the current PWM cycle.

In step S16, the flag of the first current intake state is cleared.

In step S17, the flag of the second current intake state is cleared.

Steps S15 to S17 correspond to the operation at time t13 in FIG. 3(d).

As a third example, a case where the AD conversion processing of a first current is unsuccessful at the first time and is successful at the second time, and the AD conversion processing of a second current is successful will be described.

Steps S1 to S3 are the same as steps S1 to S3 in the first example.

In step S4, when the AD conversion processing of the first current is unsuccessful (No), the processing proceeds to step S7.

Steps S7 to S12 are the same as steps S7 to S12 in the first example.

In step S13, the processing returns to step S1 because the flag of the first current intake state is not set (No).

Steps S1 to S3 are the same as steps S1 to S3 in the first example.

In step S4, whether the AD conversion processing of the first current is successful is determined, and, when the AD conversion processing is successful (Yes), the processing proceeds to step S5.

In step S5, the flag of the first current intake state is set in the memory.

In step S6, the first current (−Iu) is stored in the memory.

In step S7, the processing proceeds to step S13 because the flag of the second current intake state is set (Yes).

In step S13, the processing proceeds to step S14 because the flag of the first current intake state is set (Yes).

In step S14, the processing proceeds to step S15 because the flag of the second current intake state is set (Yes).

In step S15, a third current (Iv=−Iu−Iw) is calculated from the first current (−Iu) taken in the current PWM cycle and the second current (Iw) taken in the previous PWM cycle.

In step S16, the flag of the first current intake state is cleared.

In step S17, the flag of the second current intake state is cleared.

The present invention is not limited to the embodiment described above, and various modifications are possible.

For example, the present invention is not limited to a spatial vector modulation system, and may be, for example, a triangular wave comparison system. Further, the configuration of the motor drive control device 1 is not limited to the configuration in FIG. 1. The flowchart illustrated in FIG. 4 is also a specific example, and the present invention is not limited to this flowchart, and, for example, other processing may be inserted, a processing procedure may be changed, and parallel processing may be performed.

### REFERENCE SIGNS LIST

1 Motor drive control device
2 Motor drive unit
2a Inverter circuit
2b Pre-drive circuit
2c Current detection circuit
4 Control circuit unit
20 Motor
25u, 25v, 25w Hall element
41 Vector control unit
42 PWM generation circuit
43 Timing generation circuit
44 Analog-to-digital converter
Vcc Power supply
Q1 to Q6 Switching element
Lu Coil of U-phase
Lv Coil of V-phase
Lw Coil of W-phase
Sc Speed command signal
Vα, Vβ Voltage value
Sd Drive control signal
Tr1, Tr2 Trigger signal
Vuh, Vul, Vvh, Vvl, Vwh, Vwl Output signal
Iu, Iv, Iw Current
Shu, Shy, Shw (Sh) Hall signal
Vm Detection voltage signal
Vmd Digital voltage signal
St Timing signal

1. A motor drive control device, comprising:
a motor drive unit including an inverter circuit including a plurality of switching elements, the inverter circuit being configured to supply alternating current power to coils of three phases of a motor;
a single current detection circuit connected to a direct current line of the inverter circuit, the single current detection circuit being configured to detect a current flowing through the direct current line; and
a control circuit unit configured to perform analog-to-digital conversion processing of the current detected in the current detection circuit to take in the current, and perform PWM control on the motor drive unit, wherein
the control circuit unit
acquires, from the current detection circuit, a detection result of a first current and a second current being currents of coils of two phases among coils of three phases in a half cycle of one PWM cycle, and
when the analog-to-digital conversion processing of at least one of the first current and the second current is unsuccessful, reacquires, in the same PWM cycle or a next or subsequent PWM cycle, a detection result of only the current unsuccessful in the analog-to-digital conversion processing, and performs the analog-to-digital conversion processing of the reacquired detection current.

2. The motor drive control device according to claim 1, wherein
the control circuit unit
acquires, from the current detection circuit, a detection result of the first current and the second current in a first half of one PWM cycle, and
when the analog-to-digital conversion processing of at least one of the first current and the second current is unsuccessful, reacquires, in a first half of a next PWM cycle, a detection result of only the current unsuccessful in the analog-to-digital conversion processing, and performs the analog-to-digital conversion processing of the reacquired detection current.

3. The motor drive control device according to claim 1, wherein
the control circuit unit
acquires, from the current detection circuit, a detection result of the first current and the second current in a second half of one PWM cycle, and
when the analog-to-digital conversion processing of at least one of the first current and the second current is unsuccessful, reacquires, in a second half of a next PWM cycle, a detection result of only the current unsuccessful in the analog-to-digital conversion processing, and performs the analog-to-digital conversion processing of the reacquired detection current.

4. The motor drive control device according to claim 1, wherein
the control circuit unit
acquires, from the current detection circuit, a detection result of the first current and the second current in a second half of one PWM cycle, and
when the analog-to-digital conversion processing of at least one of the first current and the second current is unsuccessful, reacquires, in a first half of a next PWM cycle, a detection result of only the current unsuccessful in the analog-to-digital conversion processing, and performs the analog-to-digital conversion processing of the reacquired detection current.

5. The motor drive control device according to claim 1, wherein
the control circuit unit
acquires, from the current detection circuit, a detection result of the first current and the second current in a first half of one PWM cycle, and
when the analog-to-digital conversion processing of at least one of the first current and the second current is unsuccessful, reacquires, in a second half of the same PWM cycle, a detection result of only the current unsuccessful in the analog-to-digital conversion processing, and performs the analog-to-digital conversion processing of the reacquired detection current.

6. The motor drive control device according to claim 1, wherein,
when the analog-to-digital conversion processing of the current having been unable to be subjected to the analog-to-digital conversion processing is unsuccessful again, the control circuit unit repeats, in a next or subsequent PWM cycle, reacquisition of a detection result of only the current unsuccessful again in the analog-to-digital conversion processing, and the analog-to-digital conversion processing.

7. The motor drive control device according to claim 6, wherein,
when the analog-to-digital conversion processing is unsuccessful for a predetermined number of times or more, the control circuit unit acquires again a detection result of both of the first current and the second current in a half cycle of one PWM cycle.

8. A motor drive control method for performing PWM control on a motor drive unit including an inverter circuit including a plurality of switching elements, the inverter circuit being configured to supply alternating current power to coils of three phases of a motor, the motor drive control method comprising:
acquiring a detection result of a first current and a second current being currents of coils of two phases among coils of three phases in a half cycle of one PWM cycle;
performing analog-to-digital conversion processing of the first current and the second current; and
when the analog-to-digital conversion processing of at least one of the first current and the second current is unsuccessful, reacquiring, in the same PWM cycle or a next or subsequent PWM cycle, a detection result of only the current unsuccessful in the analog-to-digital conversion processing, and performing the analog-to-digital conversion processing of the reacquired detection current.
